(19) United States
(12) Patent Application Publication
(10) Pub. No.: US 2010/0060275 A1
(43) Pub. Date: Mar. 11, 2010

(54) MAGNETIC SENSOR DEVICE WITH ROBUST SIGNAL PROCESSING

(75) Inventors: Jeroen Veen, Nijmegen (NL); Theodorus Petrus Henricus Gerardus Jansen, Deurne (NL); Bart Michiel De Boer, Den Bosch (NL); Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/518,897

(22) PCT Filed: Dec. 14, 2007
(86) PCT No.: PCT/IB2007/055114

§ 371 Date: Jun. 12, 2009

(30) Foreign Application Priority Data
Dec. 18, 2006 (EP) 06126391.9

(51) Int. Cl. G01R 33/12

(52) U.S. Cl. 324/228

(57) ABSTRACT

The invention relates to a magnetic sensor device (100) comprising a magnetic field generator (1) driven with an excitation current of a first frequency (f₁) and a magnetic sensor element (e.g. a GIVER sensor (2)) driven with a sensor current (I₂) of a second frequency (f₂) for measuring reaction fields (H_{B}) generated by magnetized particles (3). In an associated evaluation unit (10), a reference component (u_{Q}) of the measurement signal (u_{GMR}) is separated that depends on the excitation current (I₁) and the sensor current (I₂) but not on the presence of magnetized particles (3). The reference component (u_{Q}) may particularly be produced by a combination of the self-magnetization (H₂) of the magnetic sensor element (2) and cross-talk related currents. The reference component (u_{Q}) may be isolated based on its phase with respect to a particle-dependent component of the measurement signal (u_{GMR}) or based on its scaling with one of the current frequencies. Monitoring of the reference component (u_{Q}) reveals variations in operating conditions, for example in the sensor gain, that can be used to calibrate the measurement results.

The invention relates to a method and a magnetic sensor device for detecting magnetized particles in a sample chamber. Moreover, it relates to the use of such a device.

From the WO 2005/010543 A1 and WO 2005/010542 A2 a magnetic sensor device is known which may for example be used in a microfluidic biosensor for the detection of (e.g. biological) molecules labeled with magnetic beads. The microsensor device is provided with an array of sensor units comprising wires for the generation of a magnetic field and Giant Magneto Resistance devices (GMRs) for the detection of stray fields generated by magnetized beads. The resistance of the GMRs is then indicative of the number of the beads near the sensor unit.

A problem with magnetic biosensors of the aforementioned kind is that the measurements are very sensitive to uncontrollable parameter variations in the applied excitation and sensor currents, sensor gain, temperature and the like.

Based on this situation it was an object of the present invention to provide means for making the measurements of magnetic sensor devices more robust against variations of their operating conditions.

This object is achieved by a magnetic sensor device according to claim 1, a method according to claim 2, and a use according to claim 11. Preferred embodiments are disclosed in the dependent claims.

The magnetic sensor device according to the present invention serves for the detection of magnetized particles, for example of magnetic beads that label target molecules in a sample. It comprises the following components:
A sample chamber in which the particles to be detected can be provided. The sample chamber is typically an empty cavity or a cavity filled with some substance like a gel that may absorb a sample; it may be an open cavity, a closed cavity, or a cavity connected to other cavities by fluid connection channels.
At least one magnetic field generator that is driven with an excitation current comprising a first frequency for generating a magnetic excitation field (at least somewhere) in the sample chamber. Saying that “a signal comprises some frequency” shall here and in the following be a short expression for the fact that the Fourier spectrum of said signal is non-zero for said frequency. The magnetic field generator may particularly be realized by at least one conductor wire on the substrate of a microelectronic sensor.
At least one associated magnetic sensor element that is driven with a sensor current comprising a second frequency for generating a measurement signal. The magnetic sensor element is associated with the aforementioned magnetic field generator in the sense that it is in the reach of effects caused by the magnetic excitation field of said generator. The magnetic sensor element may particularly comprise coils, Hall sensors, planar Hall sensors, flux gate sensors, SQUIDS (Superconducting Quantum Interference Devices), magnetic resonance sensors, magneto-restrictive sensors, or magneto-resistive elements of the kind described in the WO 2005/010543 A1 or WO 2005/010542 A2, especially a GMR (Giant Magneto Resistance), a TMR (Tunnel Magneto Resistance), or an AMR (Anisotropic Magneto Resistance) element.

The excitation current as well as the sensor current are typically provided by some power supply unit, for example a constant current source.
An evaluation unit for determining a “reference component” of the aforementioned measurement signal, wherein said reference component depends on the excitation current and/or on the sensor current and/or on the sensor gain but does not depend on the presence of magnetic particles in the sample chamber. The evaluation unit may be realized by dedicated hardware and/or by some microcomputer system together with appropriate software. It is preferably coupled by wire to the magnetic sensor element for receiving the measurement signals. The dependence of the reference component on the excitation current and/or the sensor current may particularly mean that said reference component is proportional to the excitation current and/or the sensor current and/or the sensor gain (besides some possible phase shift in the case of time-dependent signals). The sensor gain is as usual defined as the derivative of the signal of the magnetic field sensor (e.g. a voltage) with respect to the quantity to be measured (i.e. the magnetic field the sensor is exposed to). The sensor gain therefore comprises every process between the quantity to be measured and the sensor signal.

In general, a dependence of a signal on some influence should be defined in a practical sense, i.e. the signal may for example be assumed to be dependent on the influence if that influence can change the signal by more than 5% of its mean value.

A direct approach to isolate the desired particle-dependent component in the measurement signal of a magnetic sensor device is to suppress all components which do not depend on the presence of magnetic particles. In contrast to this, the described magnetic sensor device comprises an evaluation unit for processing the measurement signal in such a way that a reference component is determined that does expressively not depend on the presence of magnetized particles in the sample chamber. The reference component will therefore typically comprise information relating purely to the magnetic sensor device and the prevailing operating conditions. This information can for example be exploited when the measurement signal is interpreted with respect to the particle-dependent components of interest. If the reference component depends on the excitation current and/or the sensor current, it will share the frequency character of these currents, which eases its detection. Moreover, this dependence implies that the reference component goes back to a similar chain of physical processes as the particle-dependent signal of interest and therefore reflects the operating conditions relevant for that signal of interest. If the reference component depends on the sensor gain, it directly reflects a crucial parameter of the signal processing.

The invention further relates to a method for detecting magnetized particles in a sample chamber, the method comprising the following steps:
Generating a magnetic excitation field in the sample chamber with a magnetic field generator that is driven with an excitation current comprising a first frequency.
Generating a measurement signal with a magnetic sensor element that is driven with a sensor current comprising a second frequency.
Determining with an evaluation unit a reference component of the measurement signal that depends on the excitation current and/or on the sensor current and/or the sensor gain but not on the presence of magnetized particles in the sample chamber.

The method comprises in general form the steps that can be executed with a magnetic sensor device of the kind described above. Therefore, reference is made to the preceding description for more information on the details, advantages and improvements of that method.

In the following, preferred embodiments of the invention are described that relate both to the proposed magnetic sensor device and the method.

In a first particular embodiment of the invention, the reference component is dependent on a magnetic field acting on the magnetic sensor element. The reference component therefore includes information about the path on which magnetic fields are sensed by the magnetic sensor element, particularly about the dependence of the measurement signal on variations of the prevailing magnetic fields (i.e. about the sensor gain). In a preferred embodiment of this approach, the reference component is dependent on the self-magnetization of the magnetic sensor element which describes the effects of a magnetic field generated by the sensor current on the magnetic sensor element itself.

In another embodiment of the invention, which may particularly be realized in combination with the aforementioned one, the reference component is dependent on the capacitive and/or inductive cross-talk between the magnetic field generator and the magnetic sensor element. Such cross-talk is practically unavoidable if electrical conductors are located close to each other. While the cross-talk is usually considered as an undesirable disturbance, it is exploited here to generate a useful reference component. In a preferred embodiment, the reference component depends on the capacitive and/or inductive cross-talk (which is related to the excitation current) and simultaneously on the self-magnetization of the sensor element (which is related to the sensor current) in such a way that it comprises the product of the sensor and the excitation current, as well as the sensor gain. The reference component then shows the same frequency dependence as the signal of interest (which depends—via sensed magnetic reaction fields of magnetized particles—on the excitation current and the sensor current) and therefore reflects the relevant operating conditions for this signal.

In a further development of the invention, variations of the operating conditions are detected from the determined reference component. As the reference component is independent of the presence of magnetic particles, it is not changed by the introduction of magnetized particles into a sample chamber. Variations of the reference component occurring in the time before and during a measurement must therefore be due to changes in the operating conditions, i.e. such changes can be detected and separated from the influence of the magnetized particles on the measurement signal.

In another embodiment of the invention, a particle-dependent component of the measurement signal, which is indicative of the amount of magnetized particles in the sample chamber, is corrected with the help of the reference component. In combination with the aforementioned approach, said correction may particularly be based on detected variations of the operating conditions.

According to still another embodiment of the invention, the measurement signal is processed only at at least one given frequency. Such a frequency may particularly be the difference between the first and the second frequency (or the differences between all pairs of first and second frequencies, if there are several such frequencies in the excitation current and/or the sensor current). Restricting the processing to particular frequencies allows to isolate signal components which are due to particular physical effects.

There are various different possibilities to determine the reference component from the measurement signal, wherein these possibilities are of course dependent on the chosen definition of said reference component. In one preferred approach, the reference component is determined based on a phase shift between said reference component and a particle-dependent component of the measurement signal. This means that the reference component and the particle-dependent component of interest (which reflect the amount of magnetized particles) have the same frequency dependence and will therefore experience the same operating conditions of the associated hardware (amplifiers, filters etc.).

The reference component may optionally scale with the first and/or with the second frequency, i.e. be directly proportional to said frequency or to a function of said frequency. In this case, the reference component may be determined based on said scaling. Such a determination typically comprises the application of two different frequencies, wherein differences between the resulting measurement signals can be attributed to the reference component.

The invention further relates to the use of the magnetic sensor device described above for molecular diagnostics, biological sample analysis, and/or chemical sample analysis, particularly the detection of small molecules. Molecular diagnostics may for example be accomplished with the help of magnetic beads that are directly or indirectly attached to target molecules.

These and other aspects of the invention will be apparent from and elucidated with reference to the embodiment(s) described hereinafter. These embodiments will be described by way of example with the help of the accompanying drawings in which:

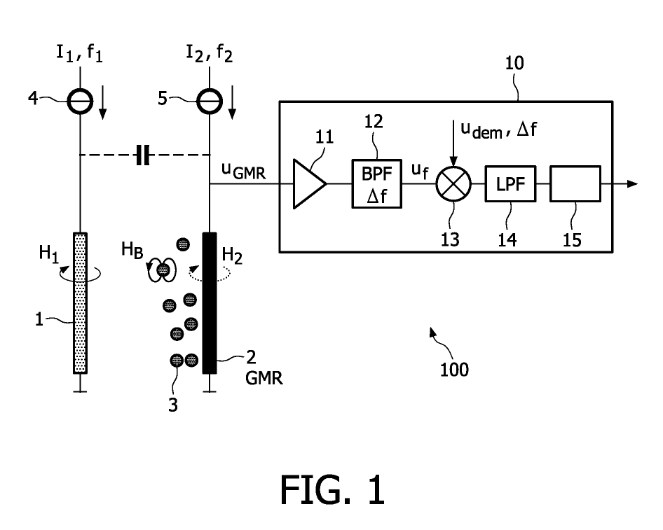

FIG. 1 shows a schematic circuit diagram of a magnetic sensor device according to the present invention;

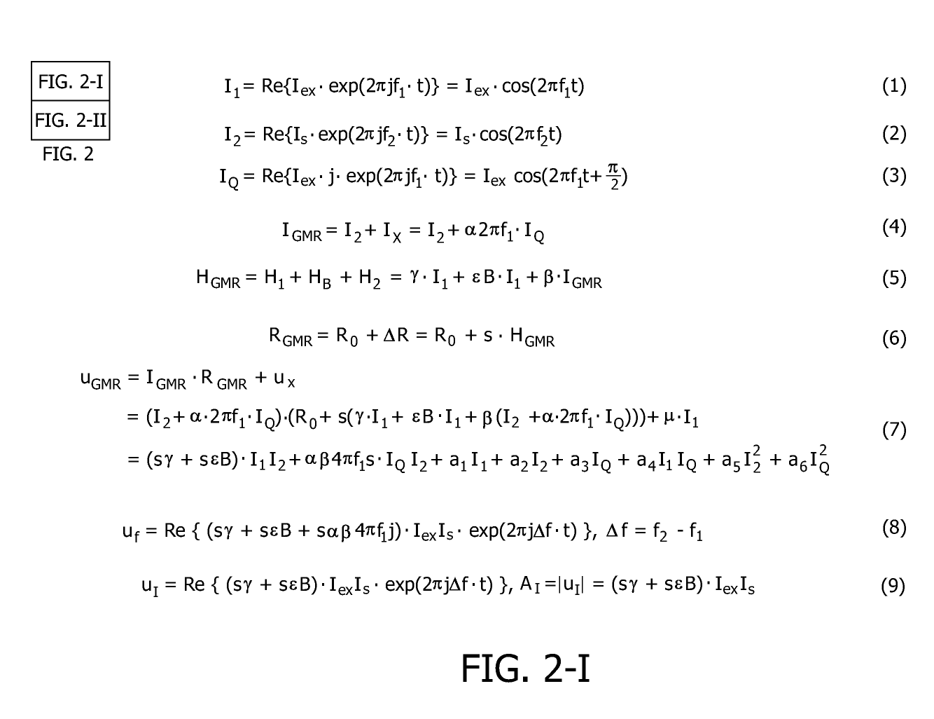

FIG. 2 summarizes mathematical expressions related to the measurement approach of the present invention;

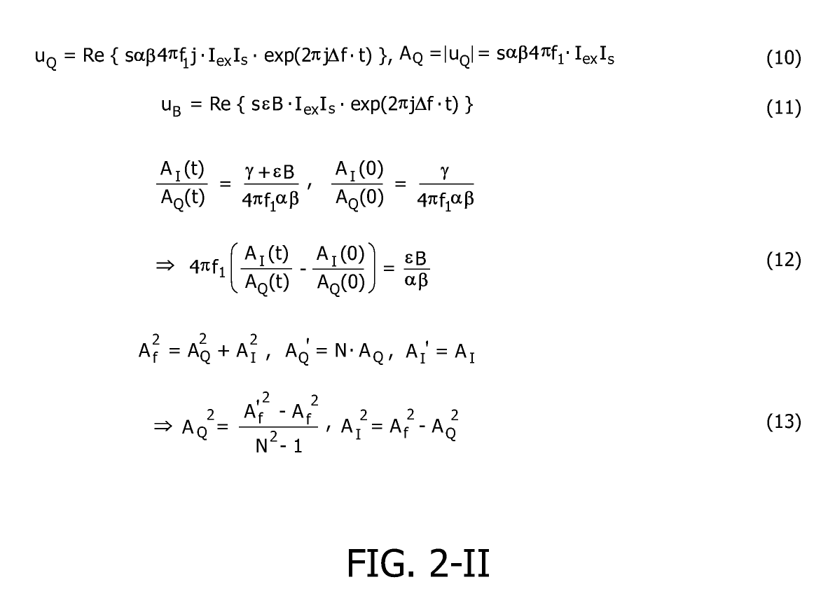

FIG. 3 illustrates the components of a measurement signal (before and after introduction of magnetized beads) at Δf in the complex plane;

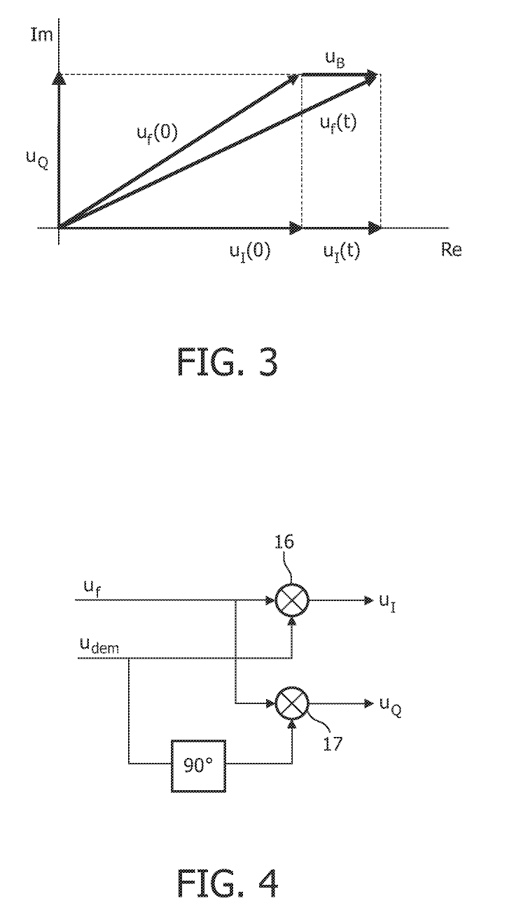

FIG. 4 shows a detection circuit that can be used to determine the quadrature component u_{Q} and the in-phase component u_{I} in the measurement signal of FIG. 3;

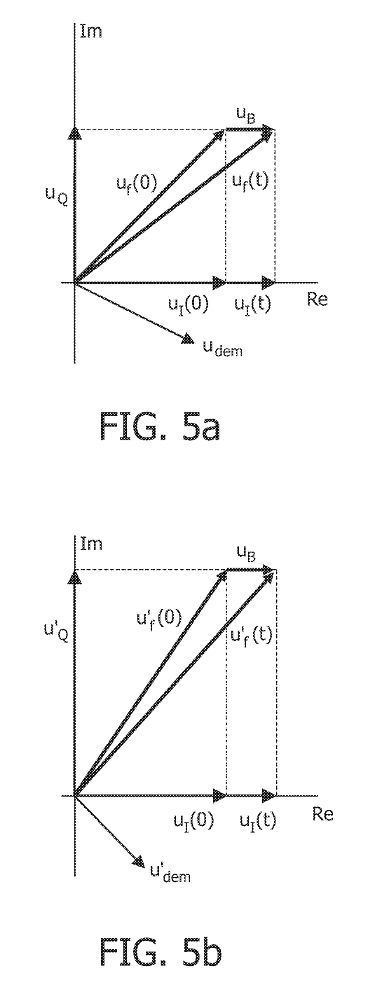

FIG. 5 shows similarly to FIG. 3 components of measurement signals at two different excitation frequencies before and after introduction of magnetized beads.

Like reference numbers in the Figures refer to identical or similar components.

FIG. 1 illustrates a microelectronic magnetic sensor device according to the present invention in the particular application as a biosensor for the detection of magnetically interactive particles, e.g. superparamagnetic beads 3, in a sample chamber. Magneto-resistive biochips or biosensors have promising properties for bio-molecular diagnostics, in terms of sensitivity, specificity, integration, ease of use, and costs. Examples of such biochips are described in the WO 2003/054566, WO 2003/054523, WO 2005/010542 A2, WO 2005/010543 A1, and WO 2005/038911 A1, which are incorporated into the present application by reference.

The magnetic sensor device 100 shown in FIG. 1 comprises at least one magnetic field generator which may be realized as a conductor wire 1 on a substrate (not shown) or which may be located outside the sensor chip. The field generator 1 is driven by a current source 4 with a sinusoidal excitation current I_{I} of a first frequency f₁ for generating an alternating external magnetic field H₁ in an adjacent sample chamber. The excitation current I₁ is expressed in equation (1) of FIG. 2 with the help of a complex representation and a (constant, real) amplitude Iₑₓ.

The generated external magnetic field H₁ magnetizes beads 3 in the sample chamber, wherein said beads 3 may for instance be used as labels for (bio-) molecules of interest (for more details see cited literature). Magnetic reaction fields H_{B} generated by the beads 3 then affect (together with the excitation field H₁) the electrical resistance of a nearby Giant Magneto Resistance (GMR) sensor element 2.

For measuring the magnetic reaction field H_{B}, a sinusoidal sensor current I₂ of frequency f₂ is generated by a further current source 5 and conducted through the GMR sensor element 2. This sensor current I₂ is expressed in equation (2) in a complex representation and with a (constant, real) amplitude Iₛ.

The voltage u_{GMR} that can be measured across the GMR sensor 2 then provides a sensor signal indicative of the resistance of the GMR sensor 2 and thus of the magnetic fields it is subjected to.

FIG. 1 further indicates by a capacitor and dashed lines a parasitic capacitive coupling between the excitation wire 1 and the GMR sensor 2. This capacitive coupling and/or an additional inductive coupling between the excitation wire 1 and the GMR sensor 2 induces a cross-talk component u_{X} of the measurement voltage u_{GMR} and an associated additional cross-talk current I_{X} through the GMR sensor 2. The cross-talk current I_{X} is proportional to the excitation current I₁, but phase shifted by 90°. The cross-talk current I_{X} and the sensor current I₂ together yield the total current I_{GMR} through the GMR sensor 2. The corresponding mathematical description of the mentioned currents is given in equations (3) and (4), wherein α is a constant.

FIG. 1 further shows that the sensor current I_{GMR} induces a self-magnetization with a field H₂ acting on the GMR sensor 2. Equation (5) summarizes the total magnetic field H_{GMR} the GMR sensor 2 is exposed to, wherein β, γ, and ε are constants and B is the bead density on the surface of the sensor that is looked for (assuming a uniform distribution of beads on the surface).

Equation (6) expresses the total resistance of the GMR sensor 2, R_{GMR}, as the sum of a constant (ohmic) term R₀ and a variable term ΔR that depends via the sensor gain s on the total magnetic field H_{GMR} prevailing in the GMR element 2.

Equation (7) gives the measurement signal u_{GMR} that is generated by the GMR sensor 2 and processed by an evaluation unit 10 (FIG. 1), wherein μ, a₁, a₂, a₃, a₄, a₅, a₆ are constants. This measurement signal u_{GMR} is composed of the (ohmic) voltage drop across the GMR sensor 2 and the additional cross-talk voltage u_{X} mentioned above. As can be seen from this equation, the measurement signal u_{GMR} comprises several components which are proportional to different products of the excitation current I₁, the sensor current I₂ and the “quadrature current” I_{Q} defined in equation (3). Using equations (1)-(3) and trigonometric identities, it can be shown that these components correspond to particular frequencies. In particular, the products I₁·I₂ and I_{Q}·I₂ consist of frequency components at the difference frequency Δf=(f₁−f₂) and at (fᵢ+f₂) which appear in no other product. By an appropriate processing of the measurement signal u_{GMR} in the evaluation unit 10, i.e. by passing it through a band-pass filter 12 (after amplification in amplifier 11) centered at the difference frequency Δf, the filtered signal u_{f} according to equation (8) is obtained. The difference frequency Δf is chosen such that the thermal noise of the GMR sensor 2 dominates the 1/f noise introduced by the amplifier 11 (i.e. chopping). In order to produce the quantity of interest, namely amplitude variation of the signal u_{f} at Δf, which is a measure for the amount of beads on the sensor, the signal u_{f} is demodulated in a demodulator 13 using a demodulation signal u_{dem} of the difference frequency Δf that is in phase with the information signal. After demodulation, the signal is low-pass filtered in a low-pass filter 14 and optionally further processed in a module 15, e.g. a workstation.

A problem of the described magnetic sensor is that the sensor sensitivity s may vary during measurements. Moreover, variations of the sensor current amplitude Iₛ and the excitation current amplitude Iₑₓ may occur, as well as gain and phase variations in the pre-processing electronics. It is therefore desirable to provide a calibration signal (called “reference component” in the following) without the use of a reference sensor, wherein such a reference component allows compensation for variations in the sensor sensitivity s, as well as in the sensor and excitation currents and in the measurement electronics.

The aforementioned objective is achieved by a decomposition of the (complex) sensor signal u_{f} of equation (8) in an “in-phase” component and a “quadrature” component. This is illustrated in FIG. 3, which shows typical filtered measurement signals u_{f}(0) and u_{f}(t) at Δf in the complex plane (Re, Im), wherein the times “0” and “t” refer to measurements before and after the introduction of magnetized beads into the sample chamber, respectively. The filtered measurement signals comprise the following different contributions:
1. The “quadrature-component” or shortly “Q-component” u_{Q}: As was explained above, capacitive and inductive cross-talk (inherent to the sensor geometry) give rise to a cross-talk current I_{X} through the GMR sensor with a frequency equal to the excitation frequency f₁. Furthermore, the applied sensor current I₂ gives rise to an internal magnetic field H₂ in the GMR sensor (self-biasing) at the second frequency f₂. Their product results in the Q-component u_{Q} at the difference frequency Δf, of which the phase is 90 degrees shifted with respect to the information carrying signal. According to equation (8), the amplitude of this Q-component u_{Q} is A_{Q}=|u_{Q}|=2πf₁αβsIₑₓIₛ, where α is the quotient I_{c}/I₁ of cross-talk current (I_{c}) and applied excitation current (I₁), β is the self biasing factor H₂/I_{GMR}, i.e. the magnetic field strength H₂ in the sensitive layer of the GMR sensor induced by a current I_{GMR} through the GMR, and s=ΔR/ΔH is the sensitivity of the GMR sensor.
2. The magnetic cross-talk vector u_{I}(0): The (inherent) misalignment of excitation wires 1 and GMR sensor wires 2 results in a GMR response u_{I}(0) to the magnetic field H₁ induced by the excitation current I₁. According to equation (9), u_{I}(0)=γsIₑₓIₛ where γ=H₂/I₁ is the proportionality constant between the magnetic field strength in the sensitive layer of the GMR induced by a current through the excitation wire and that current.
3. The total magnetic vector or “I-component” u_{I}(t): The I-component u_{I}(t)=u_{I}(0)+u_{B} comprises the aforementioned magnetic cross-talk u_{I}(0) and the signal of interest, u_{B}, caused by the beads. u_{I}(t) and u_{B} are given in equations (9) and (11), with ε=H_{B}/(BIₑₓ) being the proportionality constant between the magnetic field strength in the sensitive layer of the GMR induced by magnetized beads at the sensor surface and B being the bead density on the surface of the sensor.
4. The “bead vector” u_{B} according to equation (11) which represents the information carrying signal.

As was already mentioned, the vector u_{f}(0) represents the total (measurable) signal at Δf in the absence of magnetic beads (time 0), and the vector u_{f}(t) represents the total (measurable) signal at Δf in the presence of magnetic beads (time t).

The Q-component u_{Q} is determined by the self-magnetization of the GMR sensor and is independent of magnetic labels on the sensor surface. Therefore the Q-component can be used as a reference for robust processing and accurate calibration of the sensor sensitivity.

It should be noted that the parameters α, β, γ, ε are all fixed by the geometry of the sensor and will thus not change during measurements. These values may however vary among different sensors, which can be taken into account by an individual calibration procedure for each device.

It should further be noted that all vectors in FIG. 3 contain the factor sIₑₓIₛ. Therefore variations in the sensitivity s (e.g. as a result of fluctuations in temperature and/or external magnetic fields), the excitation current amplitude Iₑₓ, and the sensor current amplitude Iₛ, as well as gain variations in the pre-processing electronics, which may occur during the measurement scale both axes Re, Im equally.

According to FIG. 1, the filtered measurement signal u_{f} is demodulated with a demodulation signal u_{dem} of frequency Δf in the demodulator 13. The phase of the demodulation signal u_{dem} can be adjusted such that it is exactly orthogonal to the Q-component u_{Q} (the “spurious component”), which can for example be accomplished by temporarily making either the I-component or the Q-component the dominant signal contribution. With such an adjusted phase of the demodulation signal, only the I-component u_{I} is demodulated while the Q-component is suppressed.

In contrast to this, the application of a full IQ-detector is proposed here, wherein said detector determines both the I-component as well as the Q-component. The Q-component then provides the desired reference component serving as a calibration signal without the use of a reference sensor. FIG. 4 shows an example of such a IQ-detector. It comprises two demodulators 16 and 17 which are provided with the original demodulation signal u_{dem} and a 90°-phase-shifted demodulation signal, respectively.

The amplitudes A_{I} and A_{Q} of the I-component and the Q-component are defined in equations (9) and (10). According to equation (12), the ratio of these amplitudes A_{I} and A_{Q} provides a quantity that is independent of the sensor sensitivity and the applied current amplitudes, where the constants α, β, γ, ε are all fixed by the sensor geometry and B is the bead density. Calculating the ratio A_{I}/A_{Q} in the absence of beads (i.e. at time 0 prior to a biological test) and at time t in the presence of beads, therefore allows to determine the bead density B independent of the (possibly time-variable) sensor sensitivity and the applied currents.

In the following, another method than using an IQ-detector for the determination of the I-component and the Q-component will be described with reference to FIG. 5. This method is based on the realization that the Q-component u_{Q}, which results from capacitive and inductive cross-talk, is linearly dependent on the excitation frequency f₁ according to equation (10). By introducing a second excitation signal with the same magnitude, but with a frequency f₁′ of a factor N higher than the original frequency f₁, a second differential component will occur resulting from the f₂-modulation of the sensor current, namely at Δf′=N·f₁−f₂, where N is a rational number. The magnitude of the I-component is not affected by this frequency shift. However, the Q-component u_{Q}′ becomes N times higher. This is shown in the right diagram (b) of FIG. 5, where symbols with a dash generally refer to measurements with increased frequency N·f₁. While the sensor current frequency f₂ is kept constant in the shown example for notational convenience, this is not necessary.

Instead of making an orthogonal decomposition of the filtered sensor output signal u_{f}, in this embodiment only the amplitudes A_{f} and A_{f}′ of the sensor signal are measured at the difference frequencies Δf=f₁−f₂ and Δf′=N·f₁−f₂, i.e. the lengths of vectors u_{f}(0), u_{f}(t), u_{f}′(0), u_{f}′(t).

It should be noted that the phase transfer of the pre-processing electronics at Δf and Δf′ may be different, which results in a rotation of the axes of diagram (b) with respect to diagram (a). This effect is taken into account here by assigning different demodulation vectors u_{dem}, u_{dem}′.

Again the amplitudes A_{f} and A_{f}′ of the measurement vectors u_{f}, u_{f}′ can be detected at time 0 in the absence of beads, i.e. prior to the assay experiment, and then at time t in the presence of beads. From measurements with both frequencies f₁ and N·f₁, the amplitude A_{Q} of the Q-component u_{Q} can then be extracted according to equation (13), which is valid for both times 0 and t. It is assumed in this respect that amplification of the electronics is equal for Δf and Δf′. This can be accomplished by choosing the second excitation frequency f₁′ and a second sensor frequency f₂′ such that Δf and Δf′ are close, e.g. Δf−Δf′=10 kHz. Alternatively, the frequencies can be chosen such that Δf=Δf′, and the two measurements can be time-multiplexed.

Equation (13) further contains an expression for the magnitude A₁ of the in-phase I-component u_{I} (valid both at time 0 and t). With these relations, the same calculations as in equation (12) can be done, i.e. the bead density B can be determined independent of the sensor sensitivity s and the applied currents.

While the invention was described above with reference to particular embodiments, various modifications and extensions are possible, for example:
In addition to molecular assays, also larger moieties can be detected with magnetic sensor devices according to the invention, e.g. cells, viruses, or fractions of cells or viruses, tissue extract, etc.
The detection can occur with or without scanning of the sensor element with respect to the biosensor surface.
Measurement data can be derived as an end-point measurement, as well as by recording signals kinetically or intermittently.
The magnetic particles serving as labels can be detected directly by the sensing method. As well, the particles can be further processed prior to detection. An example of further processing is that materials are added or that the (bio)chemical or physical properties of the label are modified to facilitate detection.
The device and method can be used with several biochemical assay types, e.g. binding/unbinding assay, sandwich assay, competition assay, displacement assay, enzymatic assay, etc.
The device and method are suited for sensor multiplexing (i.e. the parallel use of different sensors and sensor surfaces), label multiplexing (i.e. the parallel use of different types of labels) and chamber multiplexing (i.e. the parallel use of different reaction chambers).
The device and method can be used as rapid, robust, and easy to use point-of-care biosensors for small sample volumes. The reaction chamber can be a disposable item to be used with a compact reader, containing the one or more magnetic field generating means and one or more detection means. Also, the device, methods and systems of the present invention can be used in automated high-throughput testing. In this case, the reaction chamber is e.g. a well plate or cuvette, fitting into an automated instrument.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A magnetic sensor device (100) for detecting magnetized particles (3), comprising
a sample chamber in which the particles (3), can be provided;
at least one magnetic field generator (1) that is driven with an excitation current (I₁) comprising a first frequency (f₁) for generating a magnetic excitation field (H₁) in the sample chamber;
at least one associated magnetic sensor element (2) that is driven with a sensor current (I₂) comprising a second frequency (f₂) for generating a measurement signal (u_{GMR});
an evaluation unit (10) for determining a reference component (u_{Q}) of the measurement signal (u_{GMR}) that depends on the excitation current (I₁) and/or on the sensor current (I₂) and/or on the sensor gain (s) but not on the presence of magnetized particles (3) in the sample chamber.

2. A method for detecting magnetized particles (3) in a sample chamber, the method comprising the following steps:
generating a magnetic excitation field (H₁) in the sample chamber with a magnetic field generator (1) that is driven with an excitation current (I₁) comprising a first frequency (f₁);
generating a measurement signal (u_{GMR}) with a magnetic sensor element (2) that is driven with a sensor current (I₂) comprising a second frequency (f₂);
determining with an evaluation unit (10) a reference component (u_{Q}) of the measurement signal (u_{GMR}) that depends on the excitation current (I₁) and/or on the sensor current (I₂) and/or on the sensor gain (s) but not on the presence of magnetized particles in the sample chamber.

3. The magnetic sensor device (100) according to claim 1,
characterized in that the reference component (u_{Q}) is dependent on a magnetic field (H₂) acting on the magnetic sensor element (2), particularly on a self-magnetization of the magnetic sensor element.

4. The magnetic sensor device (100) according to claim 1,
characterized in that the reference component (u_{Q}) is dependent on capacitive and/or inductive cross-talk between the field generator (1) and the magnetic sensor element (2).

5. The magnetic sensor device (100) according to claim 1,
characterized in that variations of the operating conditions are detected from the determined reference component (u_{Q}).

6. The magnetic sensor device (100) according to claim 1,
characterized in that a particle-dependent component of the measurement signal (u_{GMR}) is corrected with the help of the determined reference component (u_{Q}).

7. The magnetic sensor device (100) according to claim 1,
characterized in that only given frequencies of the measurement signal (u_{GMR}) are processed, particularly the difference (Δf) between the first frequency (f₁) and the second frequency (f₂).

8. The magnetic sensor device (100) according to claim 1,
characterized in that the reference component (u_{Q}) is determined based on a phase shift with respect to a particle-dependent component (u_{I}) of the measurement signal (u_{GMR}).

9. The magnetic sensor device (100) according to claim 1,
characterized in that the reference component (u_{Q}) scales with the first frequency (f₁) and/or the second frequency (f₂), and that it is determined based on this scaling.

10. The magnetic sensor device (100) according to claim 1,
characterized in that the magnetic sensor element (2) comprises a coil, a Hall sensor, a planar Hall sensor, a flux gate sensor, a SQUID, a magnetic resonance sensor, a magneto-restrictive sensor, or a magneto-resistive element like a GMR (2), an AMR, or a TMR element.

11. Use of the magnetic sensor device (100) according to claim 1 for molecular diagnostics, biological sample analysis, and/or chemical sample analysis, particularly the detection of small molecules
